(19) United States
(12) Patent Application Publication
(10) Pub. No.: US 2026/0327087 A1
(43) Pub. Date: Oct. 22, 2026

(54) POLISHING SLURRY AND METHOD OF MANUFACTURING SEMICONDUCTOR DEVICE

(71) Applicant: SAMSUNG ELECTRONICS CO., LTD., Suwon-si (KR)

(72) Inventors: Feifei FANG, Suwon-si (KR); Fedosya KALININA, Suwon-si (KR); Sang Soo JEE, Suwon-si (KR); Jung Hoon LEE, Suwon-si (KR); Yoonseok KO, Suwon-si (KR); Younhwa KANG, Suwon-si (KR)

(21) Appl. No.: 19/635,890

(22) Filed: Apr. 1, 2026

(30) Foreign Application Priority Data
Apr. 21, 2025 (KR) 10-2025-0051816

(51) Int. Cl. C01G 1/02; H10P 52/40

(52) U.S. Cl. CPC C01G 1/02; H10P 52/402; H10P 52/403; H10P 52/407; H10P 52/409

(57) ABSTRACT

The present disclosure relates to a polishing slurry comprising an abrasive, plate-shaped organic particles having a hardness lower than the abrasive, and a dispersion medium, and a method of manufacturing a semiconductor device using the polishing slurry.

### CROSS-REFERENCE TO RELATED APPLICATION

This U.S. nonprovisional patent application claims priority under 35 U.S.C. § 119 to Korean Patent Application No. 10-2025-0051816 filed in the Korean Intellectual Property Office on Apr. 21, 2025, and all the benefits accruing therefrom under 35 U.S.C § 119, the disclosure of which in its entirety is incorporated herein by reference.

### BACKGROUND

### 1. Field

The present disclosure relates to a polishing slurry and a method of manufacturing a semiconductor device.

### 2. Description of the Related Art

Recently, due to the miniaturization of electronic devices and the subsequent miniaturization of integrated circuits, various methods of forming microstructures such as metal wires with a width of several nanometers, contact holes, or shallow trench isolations have been studied.

In forming such microstructures, polishing processes may be performed to make the surface of the microstructures flat and smooth, and chemical mechanical polishing (CMP) may be one of the polishing processes. Chemical mechanical polishing is a process of polishing an object to be polished by providing a polishing slurry.

### SUMMARY

In order to improve the chemical mechanical polishing performance, a polishing rate such as material removal rate may be increased in order to polish an object. However, when an abrasive with a relatively large particle size is used to increase the polishing rate, a large amount of scratch defects may occur on the surface of the object to be polished due to the abrasive, and such a large amount of scratch defects may cause defects in, for example, a semiconductor device.

An embodiment provides a polishing slurry capable of removing material from the object to be polished at a high polishing rate while reducing or preventing defects on the surface of the object to be polished.

An embodiment provides a method of manufacturing the semiconductor device using the polishing slurry.

According to one embodiment, a polishing slurry includes an abrasive, plate-shaped organic particles having a lower hardness than the abrasive, and a dispersion medium.

The abrasive and the plate-shaped organic particles may each be dispersed in the dispersion medium.

The plate-shaped organic particles may be negatively or positively charged in the polishing slurry.

At the pH of the polishing slurry, the zeta potential of the abrasive and the plate-shaped organic particles may each be greater than 0 or each be less than 0.

A width of the plate-shaped organic particles may be about 100 nanometers (nm) to 10 micrometers (μm), and a ratio of the width to a thickness of the plate-shaped organic particles may be greater than or equal to about 2.5.

A Mohs hardness of the plate-shaped organic particles may be 1 to 5.

A density of the plate-shaped organic particles may be less than about 2.0 grams per cubic centimeter.

The abrasive may include an oxide, nitride, fluoride, carbon material, or a combination thereof, having an average size of less than about 100 nm.

The plate-shaped organic particles may include a polymer including a structural unit containing an aromatic ring, a structural unit derived from a compound with at least one amino group, or a combination thereof.

The abrasive may include silica, ceria, alumina, zirconia, titania, silicon nitride, aluminum nitride, zirconium nitride, titanium nitride, calcium fluoride, selenium fluoride, tellurium fluoride, silicon carbide (SiC), diamond, fullerene, derivatives thereof, or a combination thereof, and the plate-shaped organic particles may include a polymer including a structural unit derived from a substituted or unsubstituted aminobenzene, a structural unit derived from a substituted or unsubstituted aminonaphthalene, a structural unit derived from a substituted or unsubstituted phenol compound, a structural unit derived from a substituted or unsubstituted polycyclic aromatic hydrocarbon, a structural unit derived from a substituted or unsubstituted aromatic isocyanate, a structural unit derived from a substituted or unsubstituted aromatic ether ketone, a structural unit derived from a substituted or unsubstituted aromatic azo compound, a structural unit derived from a substituted or unsubstituted aromatic amide, a structural unit derived from a substituted or unsubstituted aromatic imide, a structural unit derived from a substituted or unsubstituted chalcogen-containing aromatic ring, or a combination thereof.

The abrasive and the plate-shaped organic particles may each be included in the polishing slurry in an amount of about 0.01 to 20 weight percent (wt %).

According to another embodiment, a polishing slurry includes an abrasive including silica, ceria, alumina, zirconia, titania, silicon nitride, aluminum nitride, zirconium nitride, titanium nitride, calcium fluoride, selenium fluoride, tellurium fluoride, SiC, diamond, fullerene, derivatives thereof, or a combination thereof, plate-shaped organic particles including a polymer including a structural unit derived from a substituted or unsubstituted aminobenzene, a structural unit derived from a substituted or unsubstituted aminonaphthalene, a structural unit derived from a substituted or unsubstituted phenol compound, a structural unit derived from a substituted or unsubstituted polycyclic aromatic hydrocarbon, a structural unit derived from a substituted or unsubstituted aromatic isocyanate, a structural unit derived from a substituted or unsubstituted aromatic ether ketone, a structural unit derived from a substituted or unsubstituted aromatic azo compound, a structural unit derived from a substituted or unsubstituted aromatic amide, a structural unit derived from a substituted or unsubstituted aromatic imide, a structural unit derived from a substituted or unsubstituted chalcogen-containing aromatic ring, or a combination thereof; and a dispersion medium.

According to another embodiment, a method of manufacturing a semiconductor device includes forming an object to be polished on a semiconductor substrate, and performing chemical mechanical polishing on the object to be polished using a polishing slurry, where the polishing slurry includes an abrasive, plate-shaped organic particles having a hardness lower than the abrasive, and a dispersion medium.

The hardness of the plate-shaped organic particles may be lower than the hardness of the object to be polished, and the hardness of the abrasive may be higher than the hardness of the object to be polished.

The plate-shaped organic particles may be negatively or positively charged in the polishing slurry, and at the pH of the polishing slurry, the zeta potential of the abrasive and the plate-shaped organic particles may each be greater than 0 or each be less than 0.

A width of the plate-shaped organic particles may be about 100 nm to 10 μm, and a ratio of the width to a thickness of the plate-shaped organic particles may be greater than or equal to about 2.5.

A density of the plate-shaped organic particles may be less than about 2.0 g/cm³, and a Mohs hardness of the plate-shaped organic particles may be 1 to 5.

The plate-shaped organic particles may include a polymer including a structural unit containing an aromatic ring, a structural unit derived from a compound with at least one amino group, or a combination thereof.

The object to be polished may include a metal, a semimetal, a dielectric, a compound semiconductor, an organic-inorganic compound, or a combination thereof. The abrasive may include silica, ceria, alumina, zirconia, titania, silicon nitride, aluminum nitride, zirconium nitride, titanium nitride, calcium fluoride, selenium fluoride, tellurium fluoride, SiC, diamond, fullerene, derivatives thereof, or a combination thereof, and the plate-shaped organic particle may include a polymer including a structural unit derived from a substituted or unsubstituted aminobenzene, a structural unit derived from a substituted or unsubstituted aminonaphthalene, a structural unit derived from a substituted or unsubstituted phenol compound, a structural unit derived from a substituted or unsubstituted polycyclic aromatic hydrocarbon, a structural unit derived from a substituted or unsubstituted aromatic isocyanate, a structural unit derived from a substituted or unsubstituted aromatic ether ketone, a structural unit derived from a substituted or unsubstituted aromatic azo compound, a structural unit derived from a substituted or unsubstituted aromatic amide, a structural unit derived from a substituted or unsubstituted aromatic imide, a structural unit derived from a substituted or unsubstituted chalcogen-containing aromatic ring, or a combination thereof.

The performance of the chemical mechanical polishing may include contacting a polishing pad with the object to be polished, and in the contacting the polishing pad with the object to be polished, plate-shaped organic particles in the polishing slurry may be arranged in a direction parallel to the surface of the polishing pad, and the abrasive may be interposed between the object to be polished and the plate-shaped organic particles to contact the object to be polished.

During chemical mechanical polishing, material from the object to be polished may be removed at a high polishing rate while effectively reducing or preventing defects on the surface of the object to be polished.

### BRIEF DESCRIPTION OF THE DRAWINGS

FIGS. 1 to 4 are cross-sectional views showing an example of a method of manufacturing a semiconductor device according to an embodiment,

FIG. 5 is a schematic view showing chemical mechanical polishing equipment according to an example,

FIG. 6 is a conceptual view showing an example of an electronic device according to an embodiment,

FIG. 7 is a scanning electron microscope (SEM) image of plate-shaped organic particles obtained in Synthesis Example 1, and

FIG. 8 is a SEM image of plate-shaped organic particles obtained in Synthesis Example 2.

### DETAILED DESCRIPTION

Example embodiments will hereinafter be described in detail, and may be easily performed by a person having an ordinary skill in the related art. However, this disclosure may be embodied in many different forms and is not to be construed as limited to the exemplary embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% ±5%, ±3%, or ±1% of the stated value.

As used herein, when a definition is not otherwise provided, “substituted” refers to replacement of hydrogen of a compound or a group by a substituent such as a halogen atom, a hydroxy group, a nitro group, a cyano group, an amino group, an azido group, an amidino group, a hydrazino group, a hydrazono group, an acyl group, a carbamyl group, a thiol group, an ester group, a carboxyl group or a salt thereof, a sulfonic acid group or a salt thereof, a phosphoric acid group or a salt thereof, a silyl group, a C1 to C20 alkyl group, a C2 to C20 alkenyl group, a C2 to C20 alkynyl group, a C6 to C30 aryl group, a C7 to C30 arylalkyl group (e.g., benzyl), a C1 to C30 alkoxy group, a C1 to C20 heteroalkyl group, a C3 to C20 heteroaryl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof.

As used herein, when a definition is not otherwise provided, “hetero” means including 1 to 4 heteroatoms selected from N, O, S, Se, Te, Si, and P.

As used herein, the term “combination” includes a mixture or a stacked structure of two or more.

As used herein, “metal” includes metals and semimetals.

Hereinafter, a polishing slurry according to an embodiment is described.

The polishing slurry may be used to planarize a solid surface, such as the surface of a semiconductor substrate (including a thin film or a layer such as a dielectric layer, a conductive layer such as a metal layer, or a semiconducting layer), or to remove steps on the solid surface in the manufacturing process of a semiconductor device.

A polishing slurry according to an embodiment includes an abrasive, plate-shaped organic particles, and a dispersion medium.

The abrasive may be an abrasive particle capable of removing all or a portion of an object to be polished, and may be applied to a solid surface covered with the object to be polished to chemically and/or physically remove material from the object to be polished. The abrasive may have a predetermined hardness that enables it to remove material from the object to be polished, and may have, for example, a hardness higher than that of the object to be polished (e.g., a metal, a semimetal, and/or a dielectric) or its oxide (e.g., a metal oxide or a semimetal oxide).

The abrasive may be, for example, spherical, plate-shaped, linear, and/or irregular particles, and the particle size (average particle size, major axis, or length) of the abrasive may be, for example, less than about 100 nm, and within the above range, may be greater than or equal to about 1 nm and less than about 100 nm, about 1 nm to about 80 nm, about 1 nm to about 50 nm, about 1 nm to 30 nm, about 1 nm to 20 nm, or about 1 nm to 10 nm. Herein, the particle size may be the average particle size in the case of spherical particles, and in the case of non-spherical particles, may mean the average of the length of the longest portion (major axis). The particle size may be measured using a particle size analyzer or evaluated from a transmission electron microscope (TEM) image or a scanning electron microscope (SEM) image. Alternatively, the particle size (for example, average particle size) may be obtained by counting the number of particles according to the particle size range using dynamic light scattering (DLS) and calculating therefrom. The average particle size may mean the diameter (D50) of the particle at which the cumulative volume in the particle size distribution is 50 volume percent (vol %).

The abrasive may include, for example, an oxide, nitride, fluoride, carbon material, or a combination thereof, and may be, for example, silica, ceria, alumina, zirconia, titania, silicon nitride, aluminum nitride, zirconium nitride, titanium nitride, calcium fluoride, selenium fluoride, tellurium fluoride, SiC, diamond, fullerene, derivatives thereof, or a combination thereof, but is not limited thereto.

The abrasive may be included in the polishing slurry in an amount of less than or equal to about 20 wt %, and may be included, for example, in an amount of about 0.001 wt % to about 20 wt %, about 0.001 wt % to about 15 wt %, about 0.001 wt % to about 10 wt %, about 0.001 wt % to about 8 wt %, about 0.001 wt % to about 5 wt %, or about 0.001 wt % to about 3 wt %.

The plate-shaped organic particles may include a flat organic particle having a thin and wide plate or sheet shape or a layered structure in which two or more plates or sheets are stacked, and, for example, the length extending in the X direction and the width extending in the Y direction may be greater than the thickness extending in the Z direction perpendicular to the X and Y directions, respectively. For example, the width and/or length of the plate-shaped organic particle may be several tens of nanometers to several tens of micrometers, and the thickness of the plate-shaped organic particle may be from angstroms to several tens of nanometers.

For example, the ratio of the width to the thickness of the plate-shaped organic particle, that is, the aspect ratio, may be greater than or equal to about 2.5, and within the above range, may be greater than or equal to about 3, greater than or equal to about 5, greater than or equal to about 7, greater than or equal to about 10, greater than or equal to about 20, greater than or equal to about 30, greater than or equal to about 50, greater than or equal to about 70, greater than or equal to about 80, or greater than or equal to about 100, and within the above range, may be less than or equal to about 1000, less than or equal to about 900, less than or equal to about 800, less than or equal to about 700, or less than or equal to about 500.

The plate-shaped organic particle may be larger than the abrasive. For example, when the longest portion of the plate-shaped organic particle is defined as the width and the portion perpendicular to the width in an in-plane of the plate-shaped plane is defined as the length, the width of the plate-shaped organic particle may be, for example, about 100 nm to about 10 μm, and within the above range, may be greater than or equal to about 200 nm, greater than or equal to about 300 nm, greater than or equal to about 400 nm, or greater than or equal to about 500 nm, and within the above range, may be less than or equal to about 7 μm, less than or equal to about 5 μm, less than or equal to about 3 μm, less than or equal to about 2 μm, or less than or equal to about 1 μm. The planar shape of the plate-shaped organic particle may be various, and may be, for example, a polygon such as a square, rectangle, or rhombus, a circle, or an amorphous shape, but is not limited thereto.

By having the above range of width and aspect ratio, the plate-shaped organic particle may implement an effective planar structure. Such a planar structure may increase the contact area with the abrasives and, as described below, may uniformly transmit pressure to a large amount of abrasives during chemical mechanical polishing, thereby increasing the polishing rate. This will be described later.

The plate-shaped organic particle may be a soft organic particle having relatively low hardness that does not directly participate in polishing. The plate-shaped organic particle may have a lower hardness than the object to be polished and, accordingly, may not polish the object to be polished even when it comes into contact with the object to be polished during chemical mechanical polishing. The plate-shaped organic particle may be an auxiliary particle that does not directly participate in the polishing of the object to be polished but may effectively transmit the load (pressure) applied from the polishing head to the abrasive.

For example, as described above, the plate-shaped organic particle may have a planar structure with a relatively high aspect ratio, so that during chemical mechanical polishing, it may not easily enter the grooves and/or pores in the polishing pad and may be arranged in a direction substantially parallel to the surface of the polishing pad. Accordingly, a space corresponding to the area of the plate-shaped organic particles may be secured between the plate-shaped organic particles and the object to be polished, and a large amount of abrasives may be interposed and arranged in that space, thereby greatly increasing the number of abrasives that may contact the object to be polished. A plurality of abrasives arranged between the plate-shaped organic particles and the object to be polished may be brought into close contact with the object to be polished with a substantially uniform pressure by receiving the load (pressure) applied from the polishing head through the plate-shaped organic particle, and accordingly, the number of abrasives contacting the object to be polished may be increased or the pressure applied from the abrasives to the object to be polished may be increased, thereby increasing the polishing rate and also improving polishing uniformity.

As described above, the plate-shaped organic particle may have relatively low hardness. As described above, since the plate-shaped organic particle does not substantially participate in polishing and may enhance the polishing performance of the abrasives, the hardness of the plate-shaped organic particle may be lower than the hardness of the object to be polished and the hardness of the abrasives that actually perform polishing, respectively.

The object to be polished may include, for example, a metal, a semimetal, a dielectric, a compound a semiconductor, an organic-inorganic compound, or a combination thereof, and, for example, a metal such as aluminum, copper, molybdenum, tungsten, or nickel, their alloys, or a metal oxide or semimetal oxide generated during the chemical mechanical polishing process; an oxide such as silicon oxide or aluminum oxide; a nitride such as silicon nitride, aluminum nitride, titanium nitride, or gallium nitride; a carbide such as silicon carbide; a semiconductor such as silicon or germanium; a compound semiconductor such as InP or GaAs; an organic-inorganic compound such as tetraethyl orthosilicate (TEOS); or a combination thereof, and the Mohs hardness of such an object to be polished may be, for example, in the range of 5.0 to 9.0.

The Mohs hardness of the abrasive may be, for example, in a range of 6.0 to 10.0, within a range higher than that of the object to be polished.

The Mohs hardness of the plate-shaped organic particle may be, for example, 1.0 to 5.0, and within the above range, may be 1.0 to 4.0, 1.0 to 3.0, or 1.0 to 2.0, within a range lower than those of the object to be polished and the abrasive, respectively. By having the hardness within the above range, the plate-shaped organic particle may not cause damage such as scratch defects to the object to be polished when contacting the object to be polished.

The difference in Mohs hardness between the abrasives and the plate-shaped organic particles may be, for example, greater than or equal to 2.0, and within the above range, may be greater than or equal to 3.0, greater than or equal to 4.0, or greater than or equal to 5.0, and within the above range, may be 2.0 to 9.0, 3.0 to 8.0, 4.0 to 7.0, or 5.0 to 6.0. By having the difference in Mohs hardness within the above range between the abrasives and the plate-shaped organic particles, polishing performance may be secured while scratch defects may not be generated on the object to be polished.

The plate-shaped organic particle may have a relatively low density and, for example, may have a lower density than a plate-shaped inorganic particle (e.g., h-BN). For example, the density of the plate-shaped organic particle may be less than about 2.0 g/cm² (at 25° C.), and within the above range, may be less than or equal to about 1.8 g/cm², less than or equal to about 1.6 g/cm², or about less than or equal to 1.4 g/cm², and within the above range, may be greater than or equal to about 1.0 and less than about 2.0 g/cm², about 1.0 to 1.8 g/cm², about 1.0 to 1.6 g/cm², or about 1.0 to 1.4 g/cm². By having a relatively low density within the above range, the plate-shaped organic particle may be uniformly dispersed in the polishing slurry without settling.

The plate-shaped organic particle may be charged in the polishing slurry and, accordingly, may have negative or positive surface charges. The plate-shaped organic particles may have surface charges of the same sign as the abrasives, and for example, when the abrasives have positive surface charges, the plate-shaped organic particles may also have positive surface charges, and, for example, when the abrasives have negative surface charges, the plate-shaped organic particle may also have negative surface charges. By including the plate-shaped organic particles having surface charges of the same sign as the abrasive as described above, an electrostatic repulsive force may effectively act between the abrasive and the plate-shaped organic particles, thereby effectively preventing or reducing aggregation and/or adsorption between the abrasive and the plate-shaped organic particles and the resulting settling.

The surface charges may be evaluated by the zeta potential. The zeta potential may represent the electrostatic potential of the particle surface at a predetermined pH and allow confirmation of the type and amount of charges carried by the particles. The zeta potential may be measured using electrophoretic mobility by electrophoresis.

The zeta potential may vary depending on the pH, and at a given pH (for example, process pH or polishing slurry pH), the plate-shaped organic particles may have a zeta potential of the same sign as the abrasives, thereby securing an electrostatic repulsive force between the plate-shaped organic particles and the abrasives. For example, the process pH or the pH of the polishing slurry may be in the range of 2.0 to 12.0, and within the above range, may be in the range of 2.0 to 10.0, 2.0 to 8.0, 2.0 to 6.5, 2.0 to 6.0, 3.0 to 6.5, 3.0 to 6.0, 3.5 to 6.5, 3.5 to 6.0, or 3.5 to 5.5. For example, the process pH or the pH of the polishing slurry may be in the range of 3.0 to 6.0.

For example, at the pH of the polishing slurry, the abrasive and the plate-shaped organic particles may maintain a zeta potential of the same sign. For example, at the pH of the polishing slurry, the zeta potentials of the abrasive and the plate-shaped organic particles may each be greater than 0 or each be less than 0. For example, when an abrasive having a zeta potential greater than 0 (that is, a positive zeta potential) at the pH of the polishing slurry is used, plate-shaped organic particles having a zeta potential greater than 0 (that is, a positive zeta potential) at the pH of the polishing slurry may be selected. For example, when an abrasive having a zeta potential less than 0 (that is, a negative zeta potential) at the pH of the polishing slurry is used, a plate-shaped organic particles having a zeta potential less than 0 (that is, a negative zeta potential) at the pH of the polishing slurry may be selected.

For example, the zeta potentials of the abrasive and the plate-shaped organic particles may each be about +5 millivolts (mV) to +140 mV, and within the above range, may be about +10 mV to +140 mV, about +10 mV to +120 mV, or about +10 mV to +100 mV. For example, the zeta potentials of the abrasive and the plate-shaped organic particles may each be about −10 mV to −140 mV, and within the above range, may be about −10 mV to −130 mV, about −10 mV to −120 mV, or about −10 mV to −100 mV.

For example, the difference between the zeta potential of the plate-shaped organic particles and the zeta potential of the abrasive at the pH of the polishing slurry may be greater than or equal to about 10 mV, greater than or equal to about 20 mV, or greater than or equal to about 30 mV, and within the above range, may be about 10 mV to 100 mV, about 20 mV to 100 mV, about 30 mV to 100 mV, about 10 mV to 80 mV, about 20 mV to 80 mV, or about 30 mV to 80 mV. By having the difference in zeta potential between the plate-shaped organic particles and the abrasive within the above range at the pH of the polishing slurry, a stronger electrostatic repulsive force may act between the plate-shaped organic particles and the abrasive, thereby more effectively preventing or reducing aggregation and/or adsorption between the plate-shaped organic particles and the abrasives and the resulting settling.

The plate-shaped organic particles may include an organic material capable of satisfying the above-described shape, size, hardness, density, and charge characteristics, and, for example, may include a polymer (including oligomer). The polymer may, for example, have a lamella structure. The polymer may, for example, include a structural unit (repeating unit) including an aromatic ring, a structural unit (repeating unit) derived from a compound with at least one amino group, or a combination thereof, and may effectively implement the above-described planar structure by π-π stacking of adjacent aromatic rings. Herein, the aromatic ring may include an aromatic hydrocarbon ring, an aromatic heterocycle, or a combination thereof. The polymer may be doped with a small amount of dopant to provide charged particles, but is not limited thereto.

For example, the polymer may include a structural unit derived from a substituted or unsubstituted aminobenzene (for example, a substituted or unsubstituted aniline), a structural unit derived from a substituted or unsubstituted aminonaphthalene, a structural unit derived from a substituted or unsubstituted phenol compound, a structural unit derived from a substituted or unsubstituted polycyclic aromatic hydrocarbon (for example, naphthalene, perylene, anthracene, tetracene, etc.), a structural unit derived from a substituted or unsubstituted aromatic isocyanate, a structural unit derived from a substituted or unsubstituted aromatic ether ketone, a structural unit derived from a substituted or unsubstituted aromatic azo compound, a structural unit derived from a substituted or unsubstituted aromatic amide, a structural unit derived from a substituted or unsubstituted aromatic imide, a structural unit derived from a substituted or unsubstituted chalcogen-containing aromatic ring, or a combination thereof, but is not limited thereto.

The plate-shaped organic particles may be obtained by mixing the above-described organic material (for example, polymer) and an oxidizing agent in a solvent (dispersion medium), and then polymerizing.

The oxidizing agent may, for example, include ammonium peroxide, ammonium persulfate, ammonium perchlorate, benzoyl peroxide, benzoyl persulfate, benzoyl perchlorate, hydrogen peroxide, methyl ethyl ketone peroxide, or a combination thereof, but is not limited thereto.

The solvent may be water or an organic solvent.

A surfactant may not be used during the synthesis of the plate-shaped organic particle, and accordingly, the polishing slurry including the plate-shaped organic particle may not include a surfactant, thereby preventing interference with polishing performance by the surfactant. The polymerization may be performed at room temperature or may be performed by additional heat treatment, and the heat treatment may, for example, be performed at about 30 to 150° C., but is not limited thereto.

The abrasive and the plate-shaped organic particles may each be individually dispersed in the polishing slurry (or in the dispersion medium), and a form in which the abrasive and the plate-shaped organic particles are combined or fixed to be integrated may be excluded.

In the polishing slurry, the abrasive and the plate-shaped organic particles may, for example, be included at a weight ratio of about 1:10 to 10:1. Within the above range, the abrasives and the plate-shaped organic particles may, for example, be included at a weight ratio of about 1:9 to 9:1, about 2:8 to 8:2, about 3:7 to 7:3, about 4:6 to 6:4, or about 5:5. For example, in the polishing slurry, the abrasive may be included in an amount equal to or greater than the plate-shaped 5 organic particles, and, for example, the abrasive and the plate-shaped organic particles may be included at a weight ratio of about 5:5 to 9:1. For example, in the polishing slurry, the abrasive may be included in an amount equal to or less than the plate-shaped organic particles, and, for example, the abrasive and the plate-shaped organic particles may be included at a weight ratio of about 5:5 to 1:9.

In the polishing slurry, the plate-shaped organic particles may be included in a volume equal to or greater than the abrasive, and, for example, the plate-shaped organic particles and the abrasive may be included at a volume ratio of about 1:1 to 30:1. Within the above range, the plate-shaped organic particles and the abrasive may be included at about 1:1 to 25:1, about 1:1 to 23:1, about 1:1 to 20:1, about 1:1 to 15:1, about 1:1 to 10:1, about 1:1 to 5:1, or about 1:1 to 3:1, but are not limited thereto.

By including the plate-shaped organic particles and the abrasive in the polishing slurry at the above weight ratio and/or volume ratio, the plate-shaped organic particles may effectively contact a plurality of abrasive particles and efficiently transmit the load applied from the polishing head to the abrasive, thereby further improving the polishing rate and polishing uniformity.

The polishing slurry may further include an oxidizing agent. The oxidizing agent may oxidize the object to be polished. For example, when the polishing slurry is applied to an object to be polished including a metal or a semimetal, it may oxidize the surface of the object to be polished to form a metal oxide or a semimetal oxide. The object to be polished oxidized by the oxidizing agent (for example, metal oxide or semimetal oxide) may have a relatively lower hardness or may be brittle compared to the metal or semimetal, and may be more effectively removed due to the difference in mechanical strength between the object to be polished and the oxidized object to be polished.

The oxidizing agent is not limited as long as it may oxidize the object to be polished, and, for example, may include hydrogen peroxide, peracetic acid, percarbonates, urea peroxide, perchloride acid, persulfates, iron(III)nitrate, hydrates thereof, or combinations thereof.

The oxidizing agent may be included in the polishing slurry in an amount of less than or equal to about 5 wt %, and within the above range, may be included in an amount of about 0.001 wt % to 5 wt %, about 0.001 wt % to 4 wt %, about 0.001 wt % to 3 wt %, about 0.001 wt % to 2 wt %, 0.001 wt % to 1 wt %, or about 0.001 wt % to 0.5 wt %.

The polishing slurry may further include an additive. The additive may include, for example, a chelating agent (oxidation controller), a dispersant, a pH adjuster, a corrosion inhibitor, a reaction catalyst, or a combination thereof.

The chelating agent (oxidation controller) may be, for example, phosphoric acid, nitric acid, citric acid, malonic acid, salts thereof, or a combination thereof, but is not limited thereto.

The dispersant may promote the dispersion of the abrasives and the plate-shaped organic particles, and, for example, may include a water-soluble monomer, a water-soluble oligomer, a water-soluble polymer, a metal salt, or a combination thereof. The weight average molecular weight of the water-soluble polymer may be, for example, less than or equal to about 10,000, and, for example, less than or equal to about 5,000, or less than or equal to about 3,000. The metal salt may include, for example, a copper salt, a nickel salt, a cobalt salt, a manganese salt, a tantalum salt, a ruthenium salt, or a combination thereof. The dispersant may be selected from, for example, poly(meth)acrylic acid, poly(meth)acrylic maleic acid, polyacrylonitrile-co-butadiene-acrylic acid, carboxylic acid, sulfonic ester, sulfonic acid, phosphoric ester, cellulose, diol, salts thereof, or a combination thereof, but is not limited thereto.

The pH adjuster may adjust the pH of the polishing slurry, and, for example, may be an inorganic acid or a salt thereof, an inorganic base, an organic acid or a salt thereof, or a combination thereof. The inorganic acid or a salt thereof may include, for example, nitric acid, hydrochloric acid, phosphoric acid, sulfuric acid, hydrofluoric acid, bromic acid, iodic acid, potassium hydroxide, sodium hydroxide, ammonium hydroxide, or a salt thereof, and the organic acid or a salt thereof may include, for example, formic acid, malonic acid, maleic acid, oxalic acid, adipic acid, citric acid, acetic acid, propionic acid, fumaric acid, lactic acid, salicylic acid, benzoic acid, succinic acid, phthalic acid, butyric acid, glutaric acid, glutamic acid, glycolic acid, lactic acid, aspartic acid, tartaric acid, or a salt thereof, but is not limited thereto.

The corrosion inhibitor may effectively prevent or reduce corrosion and/or over-etching of the object to be polished or the oxide of the object to be polished (oxidized by the oxidizing agent) during and/or after the polishing process, and, for example, may include leucine, lysine, methionine, valine, serine, cysteine, cystine, arginine, asparagine, aspartic acid, alanine, ornithine, isoleucine, threonine, tyrosine, glutamine, glutamic acid, glycine, histidine, phenylalanine, proline, urea, betaine, or a combination thereof, but is not limited thereto.

The reaction catalyst may promote the oxidation reaction of the object to be polished through the decomposition of the oxidizing agent. The reaction catalyst may be, for example, a metal ion compound capable of effectively generating radicals, and, for example, may be a catalyst used in a Fenton reaction or a Fenton-like reaction. The reaction catalyst may include, for example, cations such as iron (Fe) ion, chromium (Cr) ion, manganese (Mn) ion, cobalt (Co) ion, cerium (Ce) ion, potassium (K) ion, silver (Ag) ion, copper (Cu) ion, molybdenum (Mo) ion, niobium (Nb) ion, nickel (Ni) ion, osmium (Os) ion, lead (Pd) ion, tin (Sn) ion, titanium (Ti) ion, vanadium (V) ion, or a combination thereof, and anions such as nitrate, sulfate, fluoride, chloride, bromide, iodide, fluorate, chlorate, bromate, iodate, perchlorate, perbromate, periodate, cyanide salt, oxalate, citrate, acetate, acetyl acetonate, gluconate, or a combination thereof, but is not limited thereto. For example, the reaction catalyst may be an iron ion catalyst, and, for example, may include iron(II) nitrate, iron(III) nitrate, iron(II) sulfate, iron(III) sulfate, iron(II) oxalate, iron(III) oxalate, or a combination thereof, but is not limited thereto. Each component of the additive may independently be included in a trace amount of about 1 parts per million (ppm) to 100,000 ppm, for example, but is not limited thereto.

The polishing slurry may further include a dispersion medium capable of dissolving and/or dispersing the above-described components. The dispersion medium may include, for example, water, and may include, for example, distilled water and/or deionized water. The dispersion medium may be included as the remaining amount excluding the abrasive, plate-shaped organic particles, oxidizing agent, and various additives, which are solids.

The pH of the polishing slurry may range from 2.0 to 12.0, and within this range, may be in the range of 2.0 to 10.0, 2.0 to 8.0, 2.0 to 6.5, 2.0 to 6.0, 3.0 to 6.5, 3.0 to 6.0, 3.5 to 6.5, 3.5 to 6.0, or 3.5 to 5.5.

The polishing slurry may be applied to various objects to be polished to perform chemical mechanical polishing on the surface of the object to be polished. The object to be polished may be, for example, a metal, a semimetal, a dielectric, a compound semiconductor, an organic-inorganic compound, or a combination thereof, and may include, for example, metals such as aluminum, copper, molybdenum, tungsten, or nickel, their alloys, or metal oxides or semimetal oxides generated during the chemical mechanical polishing process; oxides such as silicon oxide and aluminum oxide; nitrides such as silicon nitride, aluminum nitride, titanium nitride, or gallium nitride; carbides such as silicon carbide; semimetals such as silicon or germanium; compound semiconductors such as InP or GaAs; organic-inorganic compounds such as tetraethyl orthosilicate (TEOS); or a combination thereof.

For example, the polishing slurry may be applied during structure formation, and may be applied to a polishing process of a conductive layer (metal layer) such as metal wiring or a polishing process of a dielectric layer such as shallow trench isolation (STI). The polishing slurry may be used to polish a conductive material such as a metal layer in a semiconductor substrate, and may be used to form a metal wire, a via, and/or an electrode from conductive layer including, for example, tungsten, molybdenum, aluminum, copper, nickel, or alloys thereof.

An example of a method of manufacturing a semiconductor device using the polishing slurry is hereinafter described. The semiconductor device may include at least one fine structure (for example, a trench, wiring, dielectric, semiconductor, or a combination thereof having a width of less than about 100 nm).

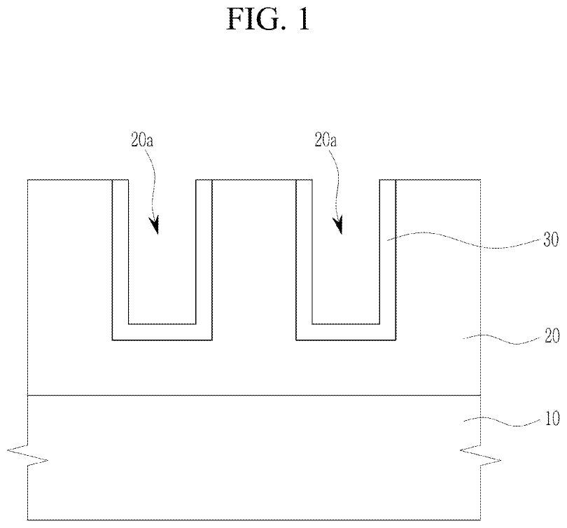

FIGS. 1 to 4 are cross-sectional views showing an example of a method of manufacturing a semiconductor device according to an embodiment.

Referring to FIG. 1, a dielectric layer 20 is formed on a semiconductor substrate 10. The dielectric layer 20 may include an oxide, a nitride, and/or an oxynitride. Subsequently, the dielectric layer 20 is etched to form an opening or trench 20a. The width of the opening 20a may be less than about 50 nm, and within this range, may be greater than or equal to about 1 nm and less than 50 nm, about 1 nm to 40 nm, about 1 nm to 30 nm, about 1 nm to 20 nm, about 1 nm to 15 nm, about 1 nm to 10 nm, or about 1 nm to 8 nm. Subsequently, a barrier layer 30 is formed on the inside wall of the opening 20a. The barrier layer 30 may include, for example, Ti, Ta, TiN, and/or TaN, but is not limited thereto.

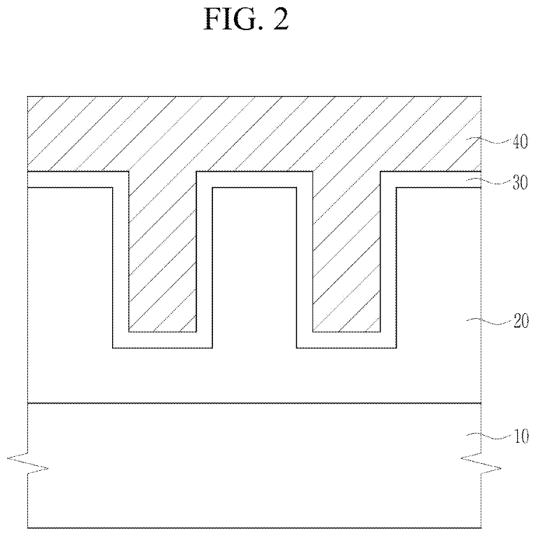

Referring to FIG. 2, the inside and the top of the trench 20a are filled or coated with a metal to form a conductive layer 40. The conductive layer 40 may include, for example, a metal such as molybdenum, tungsten, aluminum, copper, nickel, alloys thereof, or combinations thereof, but is not limited thereto.

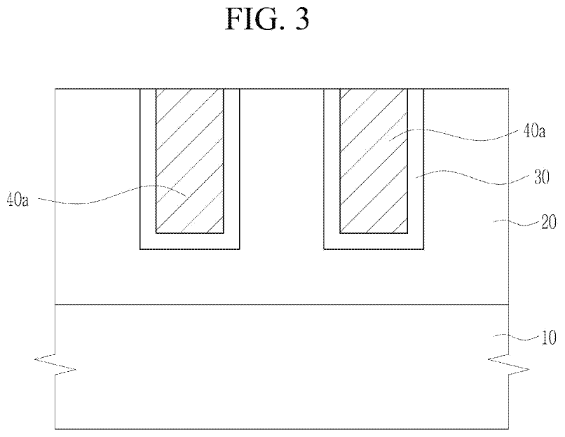

Referring to FIG. 3, the surface of the conductive layer 40 may be planarized to substantially match the surface of the dielectric layer 20 to form an embedded conductive pattern 40a. The planarization may be performed by chemical mechanical polishing using chemical mechanical polishing equipment, and the polishing slurry may be used. The chemical mechanical polishing equipment is further described below. In an embodiment, when the barrier layer 30 is a tantalulm (Ta) layer and the conductive layer 40 is a molybdenum (Mo)-containing layer, the higher the polishing selectivity of Ta to Mo in the polishing slurry, the more desirable, and for example, the higher it is than about 50:1, the more desirable.

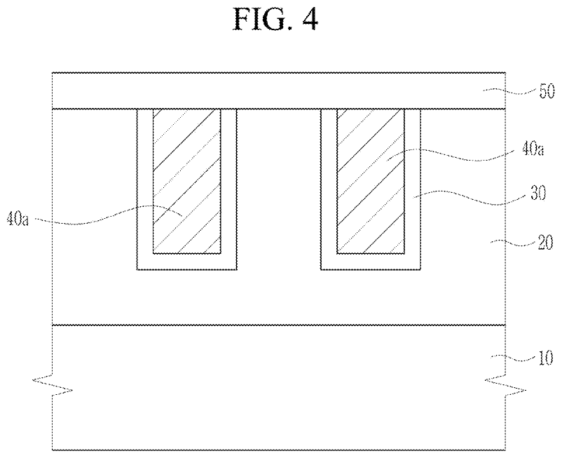

Referring to FIG. 4, a capping layer 50 is formed on the embedded conductive pattern 40a and the dielectric layer 20. The capping layer 50 may include silicon nitride (SiN) and/or SiC, but is not limited thereto.

Hereinafter, the planarization for forming the embedded conductive pattern 40a is described. The planarization may be performed by chemical mechanical polishing using chemical mechanical polishing equipment.

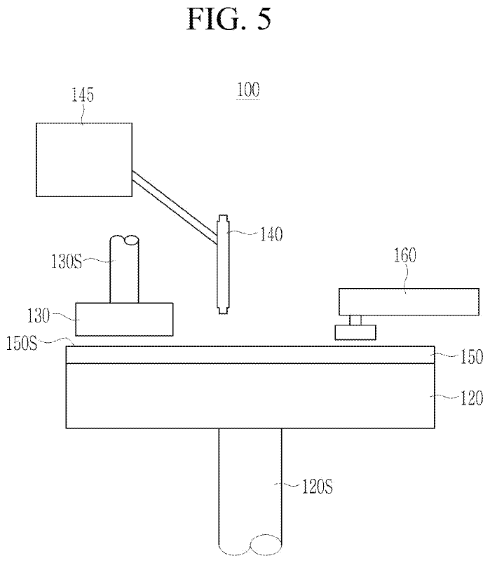

FIG. 5 is a schematic view showing chemical mechanical polishing equipment according to an example.

Referring to FIG. 5, a CMP equipment 100 according to an example may include, for example, a lower base (not shown); a platen 120 rotatably provided on an upper surface of the lower base; a polishing head 130; a polishing pad 150 on the platen 120; a pad conditioner 160; and at least one polishing slurry supply device 140 disposed adjacent to the polishing pad 150 to supply polishing slurry to the polishing pad 150.

The platen 120 may be provided rotatable on the surface of the lower base. For example, the platen 120 may receive rotational power from a motor (not shown) disposed in the lower base, and accordingly may rotate in a certain direction, such as clockwise or counterclockwise, by a rotation axis 120S perpendicular to the surface of the platen 120.

The polishing head 130 may be disposed on the platen 120 and may hold a body to be polished. The body to be polished may be a semiconductor substrate 10, such as a wafer. The polishing head 130 may include a rotating shaft 130S that rotates the body to be polished. When performing polishing, the rotation direction of the polishing head 130 may be opposite to the rotation direction of the platen 120.

The polishing pad 150 may be disposed on the platen 120 so as to be supported by the platen 120. The polishing pad 150 may rotate together with the platen 120. The polishing pad 150 may have a roughly formed polishing surface 150S. This polishing surface 150S may mechanically polish the surface of the semiconductor substrate 10 by directly contacting the semiconductor substrate 10. The polishing pad 150 may be made of a porous material with a plurality of microspaces, and the plurality of microspaces may accommodate polishing slurry. The polishing surface 150S of the polishing pad 150 may include a surface that directly contacts the body to be polished and a predetermined depth therefrom, and the predetermined depth may be about 10% to about 100%, about 20% to about 100%, about 30% to about 100%, about 40% to about 100%, or about 50% to about 100% of the thickness of the polishing pad 150. The polishing surface 150S of the polishing pad 150 may be flat, for example. The polishing surface 150S of the polishing pad 150 may have, for example, protrusions or grooves.

A pad conditioner 160 may be adjacent to the polishing pad 150 and may maintain the state of the polishing surface 150S so that the surface of the semiconductor substrate 10 may be effectively polished while the polishing process is performed.

The polishing slurry supply device 140 may be adjacent to the polishing pad 150 and may supply polishing slurry from the polishing slurry tank 145 and supply the polishing slurry to the polishing pad 150. The polishing slurry supply device 140 may include a nozzle capable of supplying polishing slurry onto the polishing pad 150 during the polishing process. The polishing slurry supply device 140 may supply the polishing slurry.

Chemical mechanical polishing may be performed, for example, by disposing a semiconductor substrate 10 and a polishing pad 150 so as to face each other, supplying the polishing slurry between the semiconductor substrate 10 and the polishing pad 150 from a polishing slurry supply device 140, and performing polishing by contacting the polishing pad 150 with the surface of the semiconductor substrate 10.

For example, the supplying of the polishing slurry may be performed at a rate of, for example, about 10 milliliters per minute (mL/min) to about 300 mL/min.

The performing of chemical mechanical polishing may include contacting the surface of the semiconductor substrate 10 (object to be polished) and the polishing pad 150, and in the contacting the polishing pad 150 and the object to be polished, the plate-shaped organic particles in the polishing slurry may be arranged in a direction substantially parallel to the surface of the polishing pad 150, and a plurality of abrasive particles with a smaller size than the plate-shaped organic particles may be interposed between the object to be polished and the plate-shaped organic particles and may polish the object to be polished by directly contacting the object to be polished.

In the performing of chemical mechanical polishing, the polishing head 130 and the platen 120 may rotate in different directions, and polishing may be performed by mechanical friction between the surface of the semiconductor substrate 10 (object to be polished) held by the polishing head 130 and the polishing pad 150 positioned on the platen 120. A pressure of about 1 pound per square inch (psi) to about 5 psi may be applied during the polishing.

Although a method of manufacturing a semiconductor device according to an embodiment is described above, it is not limited thereto, and may be applied to semiconductor devices with various structures.

The semiconductor device manufactured as described above may be included in an integrated circuit device. The integrated circuit device may be, for example, a DRAM or logic device, but is not limited thereto. The integrated circuit device may include, for example, a unit device including a transistor, a capacitor, a diode, a resistor, or a combination thereof. For example, the transistor may have various structures, and may be, for example, a FinFET, GAAFET, MBCFET, CFET, or VFET, but is not limited thereto.

The integrated circuit device may be included in various electronic devices. The electronic device may include, for example, a mobile device, computer, a laptop, tablet PC, smart watch, sensor, digital camera, electronic book, network device, vehicle navigation, Internet of Things (IoT) device, Internet of Everything (IoE) device, drone, door lock, safe, automated teller machine (ATM), security device, medical device, display device, or automotive electronic component, but is not limited thereto.

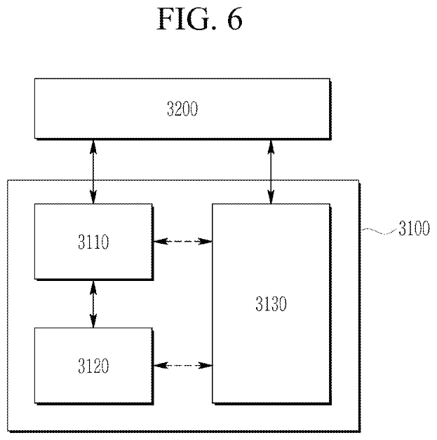

FIG. 6 is a conceptual view showing an example of an electronic device according to one embodiment.

Referring to FIG. 6, the electronic device 3100 according to an embodiment may include a memory unit 3110, an arithmetic logic unit 3120, and a control unit 3130, and these may be electrically connected. For example, the memory unit 3110, the arithmetic logic unit 3120, and the control unit 3130 may be implemented as one integrated circuit device (semiconductor chip), and, for example, may be monolithically integrated on a single substrate and implemented as a single integrated circuit device (semiconductor chip). The memory unit 3110, the arithmetic logic unit 3120, and the control unit 3130 may each independently include a transistor, a capacitor, a diode, a resistor, or a combination thereof. The electronic device 3100 may be connected to one or more input/output devices 3200.

Hereinafter, the embodiments are illustrated in more detail with reference to examples. However, these examples are exemplary, and the scope of claims is not limited thereto.

### Synthesis of Plate-Shaped Organic Particles

### Synthesis Example 1

1.2 g of aniline (manufacturer: TOKCHE) is dissolved in 700 milliliters (mL) of deionized water and mixed for 5 minutes at room temperature using a magnetic stirrer to obtain a uniform solution. Subsequently, 50 mL (17 mM) of ammonium perchlorate aqueous solution is added to the solution, stirred, and then polymerization is carried out at 25° C. for 24 hours. After completion of the polymerization, the obtained polymer is filtered with deionized water and washed until the filtrate becomes colorless to obtain plate-shaped organic particles including polyaniline.

### Synthesis Example 2

1.2 g of aniline is dissolved in 700 mL of deionized water and mixed for 5 minutes at room temperature using a magnetic stirrer to obtain a uniform solution. Subsequently, 50 mL (17 mM) of ammonium perchlorate aqueous solution is added to the solution, stirred, and then polymerization is carried out at 25° C. for 30 minutes. After completion of the polymerization, the obtained polymer is filtered with deionized water and washed until the filtrate becomes colorless to obtain plate-shaped organic particles including polyaniline.

### Evaluation I

The shape and size of the plate-shaped organic particles obtained in the Synthesis Examples are confirmed.

The shape and size of the plate-shaped organic particles are confirmed by a scanning electron microscope (SEM).

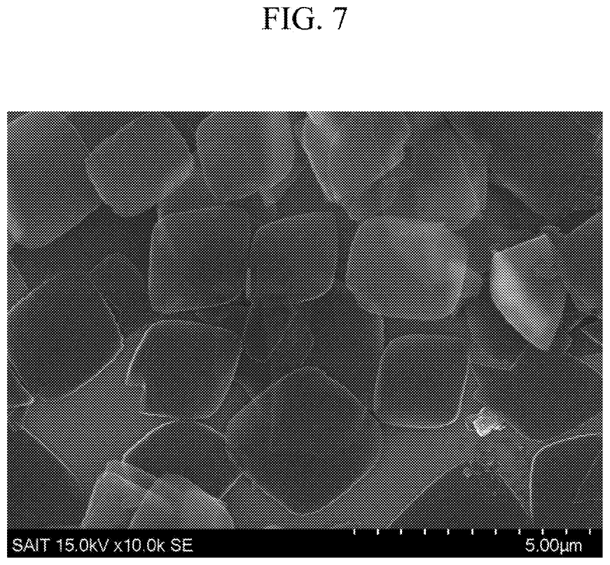

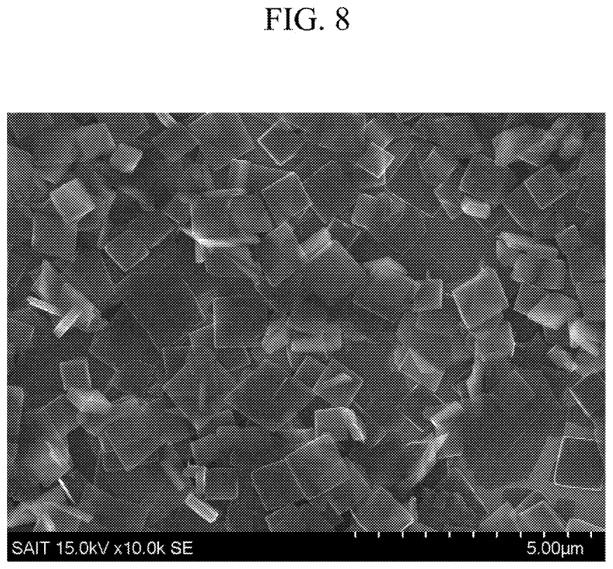

The results are shown in FIGS. 7, 8, and Table 1.

FIG. 7 is a SEM image of the plate-shaped organic particles obtained in Synthesis Example 1, and FIG. 8 is a SEM image of the plate-shaped organic particles obtained in Synthesis Example 2.

TABLE 1

| | Shape of upper | | |
|---|---|---|---|
| | surface | Width | Thickness |
| Synthesis | Rhombus | 1.5 μm-3.0 μm | 50 nm-300 nm |
| Example 1 | | | |
| Synthesis | Square | 500 nm-950 nm | 50 nm-300 nm |
| Example 2 | | | |

### Preparation of Polishing Slurry

### Preparation Example 1

0.4 wt % of ceria (D50: 25 nm, Aldrich, Mohs Hardness: 7.5 to 8), 0.1 wt % of the plate-shaped organic particles (Mohs Hardness: 2.0, Density: 1.0-1.4 g/cm³) obtained in Synthesis Example 1, a trace amount of nitric acid, a trace amount of aqueous ammonia, and the remaining amount of deionized water are mixed to prepare a polishing slurry with a pH of 5.0.

### Preparation Example 2

0.4 wt % of ceria (D50: 25 nm, Aldrich, Mohs Hardness: 7.5 to 8), 0.1 wt % of the plate-shaped organic particles (Mohs Hardness: 2.0, Density: 1.0-1.4 g/cm³) obtained in Synthesis Example 2, a trace amount of nitric acid, a trace amount of aqueous ammonia, and the remaining amount of deionized water are mixed to prepare a polishing slurry with a pH of 5.0.

### Comparative Preparation Example 1

0.4 wt % of ceria (D50: 25 nm, Aldrich, Mohs Hardness: 7.5 to 8), a trace amount of nitric acid, a trace amount of aqueous ammonia, and the remaining amount of deionized water are mixed to prepare a polishing slurry with a pH of 5.0.

### Comparative Preparation Example 2

0.1 wt % of the plate-shaped organic particles obtained in Synthesis Example 1, a trace amount of nitric acid, a trace amount of aqueous ammonia, and the remaining amount of deionized water are mixed to prepare a polishing slurry with a pH of 5.0.

### Comparative Preparation Example 3

A polishing slurry is prepared in the same manner as Comparative Preparation Example 1, except that 0.4 wt % of ceria (D50: 60 nm, Aldrich, Mohs Hardness: 7.5 to 8) is used instead of ceria (D50: 25 nm).

### Evaluation II

The zeta potential according to the ceria and pH of the plate-shaped organic particles obtained in Synthesis Example 1 is evaluated.

The zeta potential according to pH is measured using a NanoPartica particle analyzer SZ-100VZ (Horiba), and a dispersion is prepared by dispersing the plate-shaped organic particles obtained in the Synthesis Example or ceria in deionized water, and the zeta potential is measured at pH 5.0.

The results are shown in Table 2.

TABLE 2

| | Zeta potential |
|---|---|
| | (mV, @ pH 5.0) |
| Ceria | 31 |
| Plate-like organic particles | 20.7 |

Referring to Table 2, it may be confirmed that the ceria and the plate-shaped organic particles obtained in Synthesis Example 1 each exhibit a positive zeta potential at a predetermined pH. From this, it may be expected that a high electrostatic repulsive force acts between the ceria and the plate-shaped organic particles having the same sign of zeta potential, thereby increasing the dispersion stability of the polishing slurry.

### Performing Chemical Mechanical Polishing

Chemical mechanical polishing (CMP) is performed under the following conditions.
(1) CMP equipment: GNP POLI-400L (G&P Technology, Inc.)
(2) Object to be polished: 40 millimeters (mm)×40 mm silicon wafer coupon with a 20,000 angstrom (Å)-thick silicon oxide film formed thereon
(3) Polishing head rotation speed: 130 rpm
(4) Polishing platen rotation speed: 130 rpm
(5) Applied pressure: 4.5 psi
(6) Initial temperature: 24° C.
(7) Polishing pad: IT-2000 (KPX Chemical Co.)
(8) Polishing slurry: Polishing slurry according to the Preparation Examples and Comparative Preparation Examples (45° C.)
(9) Polishing slurry supply flow rate: 150 ml/min.
(10) Polishing time: 1 minute

### Evaluation IV

In the chemical mechanical polishing using the polishing slurry according to the Preparation Examples and the Comparative Preparation Examples, the polishing rate (material removal rate, MRR) for the silicon oxide film is evaluated.

The MRR is calculated using Calculation Equation 1.

MRR (angstrom per minute (Å/min))=(thickness of silicon oxide film before polishing (Å)−thickness of silicon oxide film after polishing (Å))/polishing time (min) Calculation Equation 1

In Calculation Equation 1, the thickness of the silicon oxide film is determined as the average value by measuring the thickness at the center portion of the silicon oxide film five times using a film thickness measuring device (ST5030-SL, K-MAC).

The results are shown in Table 3.

TABLE 3

| | MRR (Å/min) |
|---|---|
| Preparation Example 1 | 1791 |
| Preparation Example 2 | 2959 |
| Comparative Preparation Example 1 | 933 |
| Comparative Preparation Example 2 | <1 |

Referring to Table 3, it may be confirmed that the polishing slurries according to the Preparation Examples may advantageously increase the polishing rate for the object to be polished compared to the polishing slurries according to the Comparative Preparation Examples. Meanwhile, from the polishing rate result of the polishing slurry according to Comparative Preparation Example 2, it may be confirmed that the plate-shaped organic particles alone does not substantially perform polishing. From this, it may be confirmed that the plate-shaped organic particles may enhance the polishing of the abrasive without directly participating in the polishing.

### Evaluation V

The surface roughness of the silicon oxide film polished by chemical mechanical polishing using the polishing slurry according to the Preparation Examples and the Comparative Preparation Examples is evaluated.

The surface roughness is evaluated from the average value of the flatness of an area of 600 μm×600 μm using an atomic force microscope (AFM) (NX20, Park system Co.).

The results are shown in Table 4.

TABLE 4

| | Rq (nm) |
|---|---|
| Preparation Example 1 | 0.325 |
| Comparative Preparation Example 1 | 0.302 |
| Comparative Preparation Example 3 | 0.850 |

* Rq: Root Mean Square (RMS) Roughness

Referring to Table 4, it may be confirmed that when chemical mechanical polishing is performed using the polishing slurry according to Preparation Example 1, it may exhibit a surface roughness at about an equivalent level compared to when chemical mechanical polishing is performed using the polishing slurry according to Comparative Preparation Example 1. From this, it may be confirmed that the plate-shaped organic particles obtained in the Synthesis Example does not substantially increase scratch defects on the surface of the object to be polished.

Meanwhile, when chemical mechanical polishing is performed using the polishing slurry according to Comparative Preparation Example 3, it may be confirmed that a large number of scratches are generated on the surface of the object to be polished due to the abrasive with a relatively large particle size, resulting in high surface roughness.

When Tables 3 and 4 are considered together, it may be confirmed that when chemical mechanical polishing is performed using the polishing slurry according to the Preparation Examples, material from the object to be polished may be advantageously removed at a high polishing rate, and at the same time, defects on the surface of the object to be polished may be effectively reduced or prevented.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A polishing slurry comprising:
an abrasive,
plate-shaped organic particles, the plate-shaped organic particles having a lower hardness than the abrasive, and
a dispersion medium.

2. The polishing slurry of claim 1, wherein the abrasive and the plate-shaped organic particles are each dispersed in the dispersion medium.

3. The polishing slurry of claim 1, wherein the plate-shaped organic particles are charged negatively or positively in the polishing slurry.

4. The polishing slurry of claim 1, wherein a zeta potential of the abrasive and the plate-shaped organic particles in the polishing slurry is each greater than 0 or each less than 0 at a pH of the polishing slurry.

5. The polishing slurry of claim 1, wherein
a width of the plate-shaped organic particles is about 100 nanometers to about 10 micrometers, and
a ratio of the width to a thickness of the plate-shaped organic particles is greater than or equal to about 2.5.

6. The polishing slurry of claim 1, wherein a Mohs hardness of the plate-shaped organic particles is 1 to 5.

7. The polishing slurry of claim 1, wherein a density of the plate-shaped organic particles is less than about 2.0 grams per cubic centimeter.

8. The polishing slurry of claim 1, wherein the abrasive comprises an oxide, nitride, fluoride, carbon material, or a combination thereof, having an average size of less than about 100 nanometers.

9. The polishing slurry of claim 1, wherein the plate-shaped organic particles comprise a polymer including a structural unit containing an aromatic ring, a structural unit derived from a compound with at least one amino group, or a combination thereof.

10. The polishing slurry of claim 1, wherein
the abrasive comprises silica, ceria, alumina, zirconia, titania, silicon nitride, aluminum nitride, zirconium nitride, titanium nitride, calcium fluoride, selenium fluoride, tellurium fluoride, silicon carbide, diamond, fullerene, derivatives thereof, or a combination thereof, and
the plate-shaped organic particles comprise a polymer including a structural unit derived from a substituted or unsubstituted aminobenzene, a structural unit derived from a substituted or unsubstituted aminonaphthalene, a structural unit derived from a substituted or unsubstituted phenol compound, a structural unit derived from a substituted or unsubstituted polycyclic aromatic hydrocarbon, a structural unit derived from a substituted or unsubstituted aromatic isocyanate, a structural unit derived from a substituted or unsubstituted aromatic ether ketone, a structural unit derived from a substituted or unsubstituted aromatic azo compound, a structural unit derived from a substituted or unsubstituted aromatic amide, a structural unit derived from a substituted or unsubstituted aromatic imide, a structural unit derived from a substituted or unsubstituted chalcogen-containing aromatic ring, or a combination thereof.

11. The polishing slurry of claim 1, wherein the abrasive and the plate-shaped organic particles are each included in the polishing slurry in an amount of about 0.01 to 20 weight percent.

12. A polishing slurry comprising:
an abrasive including silica, ceria, alumina, zirconia, titania, silicon nitride, aluminum nitride, zirconium nitride, titanium nitride, calcium fluoride, selenium fluoride, tellurium fluoride, silicon carbide, diamond, fullerene, derivatives thereof, or a combination thereof,
plate-shaped organic particles including a polymer including a structural unit derived from a substituted or unsubstituted aminobenzene, a structural unit derived from a substituted or unsubstituted aminonaphthalene, a structural unit derived from a substituted or unsubstituted phenol compound, a structural unit derived from a substituted or unsubstituted polycyclic aromatic hydrocarbon, a structural unit derived from a substituted or unsubstituted aromatic isocyanate, a structural unit derived from a substituted or unsubstituted aromatic ether ketone, a structural unit derived from a substituted or unsubstituted aromatic azo compound, a structural unit derived from a substituted or unsubstituted aromatic amide, a structural unit derived from a substituted or unsubstituted aromatic imide, a structural unit derived from a substituted or unsubstituted chalcogen-containing aromatic ring, or a combination thereof, and
a dispersion medium.

13. A method of manufacturing a semiconductor device, the method comprising:
forming an object to be polished on a semiconductor substrate, and
performing chemical mechanical polishing on the object to be polished using a polishing slurry,
wherein the polishing slurry includes an abrasive, plate-shaped organic particles having a hardness lower than the abrasives, and a dispersion medium.

14. The method of claim 13, wherein
the hardness of the plate-shaped organic particles is lower than the hardness of the object to be polished, and
the hardness of the abrasive is higher than the hardness of the object to be polished.

15. The method of claim 13, wherein
the plate-shaped organic particles are charged negatively or positively in the polishing slurry, and
a zeta potential of the abrasive and the plate-shaped organic particles is each greater than 0 or each less than 0 at the pH of the polishing slurry.

16. The method of claim 13, wherein
a width of the plate-shaped organic particles is about 100 nanometers to about 10 micrometers, and
a ratio of the width to a thickness of the plate-shaped organic particles is greater than or equal to about 2.5.

17. The method of claim 13, wherein a density of the plate-shaped organic particles is less than about 2.0 grams per cubic centimeter, and a Mohs hardness of the plate-shaped organic particles is 1 to 5.

18. The method of claim 13, wherein the plate-shaped organic particles comprise a polymer including a structural unit containing an aromatic ring, a structural unit derived from a compound with at least one amino group, or a combination thereof.

19. The method of claim 13, wherein
the object to be polished comprises a metal, a semimetal, a dielectric, a compound semiconductor, an organic-inorganic compound, or a combination thereof, the abrasives comprise silica, ceria, alumina, zirconia, titania, silicon nitride, aluminum nitride, zirconium nitride, titanium nitride, calcium fluoride, selenium fluoride, tellurium fluoride, silicon carbide, diamond, fullerene, derivatives thereof, or a combination thereof, and
the plate-shaped organic particles comprise a polymer including a structural unit derived from a substituted or unsubstituted aminobenzene, a structural unit derived from a substituted or unsubstituted aminonaphthalene, a structural unit derived from a substituted or unsubstituted phenol compound, a structural unit derived from a substituted or unsubstituted polycyclic aromatic hydrocarbon, a structural unit derived from a substituted or unsubstituted aromatic isocyanate, a structural unit derived from a substituted or unsubstituted aromatic ether ketone, a structural unit derived from a substituted or unsubstituted aromatic azo compound, a structural unit derived from a substituted or unsubstituted aromatic amide, a structural unit derived from a substituted or unsubstituted aromatic imide, a structural unit derived from a substituted or unsubstituted chalcogen-containing aromatic ring, or a combination thereof.

20. The method of claim 13, wherein
the performing of chemical mechanical polishing comprises contacting a polishing pad with the object to be polished, and
in the contacting the polishing pad with the object to be polished, the plate-shaped organic particles in the polishing slurry are arranged in a direction parallel to the surface of the polishing pad, and the abrasive is interposed between the object to be polished and the plate-shaped organic particles to contact the object to be polished.
